(19) United States
(12) Patent Application Publication
(10) Pub. No.: US 2015/0228929 A1
(43) Pub. Date: Aug. 13, 2015

(54) MICROCAVITY OLED LIGHT EXTRACTION

(71) Applicant: 3M INNOVATIVE PROPERTIES COMPANY, St. Paul, MN (US)

(72) Inventors: Sergey Lamansky, Redmond, VA (US); Seong T. Lee, Woodbury, MN (US); Jonathan A. Anim-Addo, New Hope, MN (US); Ghidewon Arefe, St. Paul, MN (US); Keith L. Behrman, Bangkok (TH); James M. Nelson, Lino Lakes, MN (US); Vivian W. Jones, Woodbury, MN (US); William A. Tolbert, Woodbury, MN (US)

(21) Appl. No.: 14/420,843

(22) PCT Filed: Aug. 9, 2013
(86) PCT No.: PCT/US13/54255

§ 371 Date: Feb. 10, 2015

Related U.S. Application Data
(60) Provisional application No. 61/691,949, filed on Aug. 22, 2012.

(51) Int. Cl. H01L 51/52; H01L 27/32

(52) U.S. Cl. CPC H01L 51/5268; H01L 27/3244

(57) ABSTRACT

The present disclosure provides a light emitting device, an active matrix organic light emitting diode (AMOLED) device that includes the light emitting device, and an image display device that includes the light emitting device. In particular, the light emitting device includes a microcavity organic light emitting diode (OLED) (120), a light extraction film (110), and a high-index capping layer (122) disposed between the microcavity OLED and the light extraction film.

### RELATED APPLICATION

This application is related to the following U.S. patent application, which is incorporated herein by reference: “TRANSPARENT OLED LIGHT EXTRACTION” (Attorney Docket No. 70114US002), filed on an even date herewith.

### BACKGROUND

Organic Light Emitting Diode (OLED) devices include a thin film of electroluminescent organic material sandwiched between a cathode and an anode, with one or both of these electrodes being a transparent conductor. When a voltage is applied across the device, electrons and holes are injected from their respective electrodes and recombine in the electroluminescent organic material through the intermediate formation of emissive excitons.

In OLED devices, over 70% of the generated light is typically lost due to processes within the device structure. The trapping of light at the interfaces between the higher index organic and Indium Tin Oxide (ITO) layers and the lower index substrate layers is one cause of this poor extraction efficiency. Only a relatively small amount of the emitted light can emerge through the transparent electrode as “useful” light. Much of the light undergoes internal reflections, resulting in light being emitted from the edge of the device or trapped within the device and eventually being lost to absorption within the device after making repeated passes. Light extraction films use internal nanostructures that can reduce such waveguiding losses within the device.

Active Matrix OLED (AMOLED) displays are gaining prominence in the displays market. One of the advances that have influenced AMOLEDs' efficient market penetration has been utilization of a strong optical microcavity OLED architecture to improve axial efficiency and achieve 100% NTSC axial color gamut. At the same time, the strong microcavity approach has a number of limitations associated with both the complexity of AMOLED fabrication and with angular luminance and color performance of AMOLED devices. It is also well known that a strong microcavity is not compatible with majority of known light extraction techniques.

### SUMMARY

The present disclosure provides a light emitting device, an active matrix organic light emitting diode (AMOLED) device that includes the light emitting device, and an image display device that includes the light emitting device. In particular, the light emitting device includes a microcavity organic light emitting diode (OLED), a light extraction film, and a high-index capping layer disposed between the microcavity OLED and the light extraction film. In one aspect, the present disclosure provides a light emitting device that includes a microcavity organic light emitting diode (OLED) device having a top metal electrode configured to emit light; a capping layer having an index of refraction greater than 1.8 disposed immediately adjacent the top metal electrode; and a light extraction film disposed adjacent the capping layer.

In another aspect, the present disclosure provides an active matrix organic light emitting diode (AMOLED) device that includes an array of light emitting devices, each light emitting device having a microcavity organic light emitting diode (OLED) device having a top metal electrode configured to emit light; a capping layer having an index of refraction greater than 1.8 disposed immediately adjacent the top metal electrode; and a light extraction film disposed over the array of light emitting devices, the light extraction film adjacent the capping layer.

In yet another aspect, the present disclosure provides an image display device that includes a plurality of light emitting devices, each light emitting device having a microcavity organic light emitting diode (OLED) device having a top metal electrode configured to emit light; and a capping layer having an index of refraction greater than 1.8 disposed immediately adjacent the top metal electrode. The image display device further includes a light extraction film disposed over the plurality of light emitting devices, the light extraction film adjacent the capping layer; and an electronic circuit capable of activating each of the light emitting devices.

The above summary is not intended to describe each disclosed embodiment or every implementation of the present disclosure. The figures and the detailed description below more particularly exemplify illustrative embodiments.

### BRIEF DESCRIPTION OF THE DRAWINGS

Throughout the specification reference is made to the appended drawings, where like reference numerals designate like elements, and wherein:

FIG. 1 shows a cross-sectional schematic of a light emitting device;

FIG. 2 shows efficiency vs luminance for control and extractor-laminated devices;

FIG. 3 shows efficiency vs luminance for control and extractor-laminated devices;

FIG. 4 shows efficiency vs luminance for control and extractor-laminated devices; and

FIG. 5 shows efficiency vs luminance for control and extractor-laminated devices.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The present disclosure describes a light emitting device that includes a microcavity organic light emitting diode (OLED), a light extraction film, and a high-index capping layer disposed between the microcavity OLED and the light extraction film. Embodiments of the present disclosure relate to light extraction films and uses of them for OLED devices. Examples of light extraction films are described in U.S. Pat. Application Publication Nos. 2009/0015757 and 2009/0015142, and also in co-pending U.S. patent application Ser. No. 13/218,610 (Attorney Docket No. 67921US002).

In the following description, reference is made to the accompanying drawings that forms a part hereof and in which are shown by way of illustration. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower,” “upper,” “beneath,” “below,” “above,” and “on top,” if used herein, are utilized for ease of description to describe spatial relationships of an element(s) to another. Such spatially related terms encompass different orientations of the device in use or operation in addition to the particular orientations depicted in the figures and described herein. For example, if an object depicted in the figures is turned over or flipped over, portions previously described as below or beneath other elements would then be above those other elements.

As used herein, when an element, component or layer for example is described as forming a “coincident interface” with, or being “on” “connected to,” “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as being “directly on,” “directly connected to,” “directly coupled with,” or “directly in contact with” another element, there are no intervening elements, components or layers for example.

OLED external efficiency is a parameter to be considered for all OLED applications in the range between high-resolution displays and lighting, since it affects such important device characteristics as power consumption, luminance and lifetime. It has been demonstrated that OLED external efficiency can be limited by optical losses within the OLED stack itself (for example, waveguiding mode within high-index organic layers and indium tin oxide), within intermediate-refractive index substrates, and due to exciton quenching at the electrode (cathode or anode) metal's surface plasmon polaritons. In a device with a maximum possible internal efficiency, about 75-80% of this efficiency can be dissipated internally due to above-mentioned losses. Additionally, in display applications, more than 50% of the light can be lost in a circular polarizer used for improving, for example, Active Matrix Organic Light Emitting Diode (AMOLED) ambient contrast. The primary approach to addressing improvement of light extraction implemented in current AMOLED displays involves a strong optical microcavity, which enables some (usually about 1.5×) axial and total gains, yet can induce significant luminance and color angular problems.

OLED luminance enhancement by a factor of 1.5-2.2× has been demonstrated with nanostructured, that is sub-micron, OLED light extractors, for example in U.S. Pat. Application Publication Nos. 2009/0015757 and 2009/0015142; however, nanostructured extractors used with OLEDs having a strong microcavity behavior has not previously been demonstrated.

Microcavity OLEDs have been described, for example, in U.S. Pat. Nos. 7,800,295 and 7,719,499; and also in Journal of Display Technology, VOL. 01, NO. 2, pages 248-266 (December 2005) Wu et al., “Advanced Organic Light-Emitting Devices for Enhancing Display Performances”. Even though optical microcavities are relatively well understood, there is a lack of understanding of the poor compatibility of microcavities with other optical outcoupling methods for OLEDs, as well as a lack of practical approaches that can work synergistically with a strong microcavity. Optical modeling and experimental results indicate that while the trapped optical modes distribution is affected by presence of a strong microcavity, a significant portion of the trapped modes remains unharvested; that is, trapped within the microcavity.

The present disclosure describes a light emitting device such as an AMOLED display based on a strong microcavity OLED, where a laminated nanostructured light extraction film produces additional optical axial and integrated gains. The device also exhibits improved angular luminance and color. Additional light extraction by the nanostructured film is enabled by employing a high refractive index capping or encapsulation stack on top of the top metal electrode of the microcavity OLED device.

Strong optical microcavity design is a current industry standard in AMOLED displays for mobile applications, and therefore the design of laminated extractors as well as AMOLED optical stacks to enable additional extraction gains with strong-cavity OLED devices is desired. It is also desired to resolve angular color/luminance issues associated with the microcavity.

In one particular embodiment, the present disclosure provides an AMOLED display with integrated light extraction film (extractor) showing improved light outcoupling (efficiency) and improved wide-angle luminance and color performance due to implementation of all of the following design parameters: (a) a light extraction film (extractor) with a replicated sub-micron structure backfilled with a high refractive index material and laminated onto an AMOLED display; (b) an optical coupling material employed for extractor lamination that has a high refractive index, optical transparency, good degree of conformability into pixilated backplane and low or no effect on OLED device short- and long-term stability; and (c) a top-emissive strong microcavity OLED stack with high refractive index (n≧1.8, or n≧1.9, or n≧2.0) capping layer or thin film encapsulation construction which enables optical communication between guided or trapped optical modes inside the strong cavity device and extraction structures.

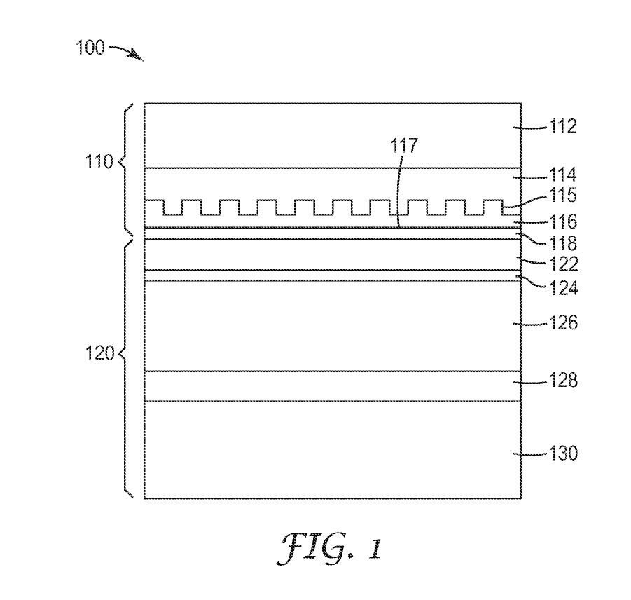

FIG. 1 shows a cross-sectional schematic of a light emitting device 100, according to one aspect of the disclosure. Light emitting device 100 includes a light extraction film 110 disposed adjacent a capping layer 122. The capping layer 122 is disposed immediately adjacent a top metal electrode 124 of a microcavity OLED device 120. In one particular embodiment, light emitting device 100 can be a novel portion of an AMOLED device, or part of an image display device including drive electronics, as known to one of skill in the art. Light extraction film 110 can include a substantially transparent substrate 112 (either flexible or rigid), a nanostructured layer 114 including nanostructures 115, and a backfill layer 116 that can form a substantially planar surface 117 over nanostructures 115. The backfill layer 116 includes a material that has an index of refraction that is greater than the index of refraction of the nanostructured layer 114. The term “substantially planar surface” means that the backfill layer planarizes the underlying layer, although slight surface variations may be present in the substantially planar surface. When the planar surface of the backfill layer is placed against the light output surface of the microcavity OLED device 120, the nanostructures at least partially enhance light output from the microcavity OLED device 120. The backfill planar surface 117 can be placed directly against the OLED light output surface or through another layer between the planar surface and light output surface.

Microcavity OLED device 120 includes a microcavity OLED having a bottom electrode 128, electroluminescent organic material layer 126, and a top metal electrode 124, and can further be disposed on a backplane 130. Top metal electrode 124 can be a cathode that is generally fabricated to be a thinner metallic layer compared to the bottom electrode 128, such that light generated in the electroluminescent organic material layer 126 can escape the microcavity OLED device 120. In some cases, the top electrode can be a partially transparent electrode comprising a metal having a thickness less than about 30 nm. Microcavity OLED device 120 further includes a capping layer 122 disposed immediately adjacent the top metal electrode 124. It has been discovered that when the capping layer 122 has a sufficiently high index of refraction, generally at least greater than the electroluminescent organic material layer 126, the efficiency of light extracted from the microcavity OLED device 120 can be improved by the light extraction film 110.

The capping layer can have an index of refraction greater than about 1.8, or greater than about 1.9, or greater than about 2.0 or more. As used herein, refractive index refers to the index of refraction for light having a wavelength of 550 nm, unless otherwise indicated. In one particular embodiment, the capping layer comprises molybdenum oxide (MoO3), zinc selenide (ZnSe), silicon nitride (SiNx), indium tin oxide (ITO), or a combination thereof. In one particular embodiment, a capping layer comprising zinc selenide can be preferred. In some cases, the capping layer comprises a thickness between about 60 nm and 400 nm. The capping layer thickness may be optimized, if desired, to provide for the most efficient coupling of the waveguided loss modes inside the OLED stack, to the extractor. While the capping layer has the above-mentioned optical function, it also in some cases can provide an additional protection of the OLED organic materials from the extraction film components, for example, from the optical coupling layer/adhesive used to apply the extraction film onto an OLED device. Thus, it may be desirable that the capping layer exhibits some level of barrier properties towards the components of the OLED light extraction film.

The light extraction film 110 is typically made as a separate film to be applied to a microcavity OLED device 120. For example, an optical coupling layer 118 can be used to optically couple light extraction film 110 to a light output surface of a microcavity OLED device 120. Optical coupling layer 118 can be applied to the light extraction film 110, the microcavity OLED device 120, or both, and it can be implemented with an adhesive to facilitate application of the light extraction film 110 to the microcavity OLED device 120. As an alternative to a separate optical coupling layer 118, the backfill layer 116 may be comprised of a high index adhesive, so that the optical and planarizing functions of the backfill layer 116, and the adhering function of the adhesive optical coupling layer 118, are performed by the same layer. Examples of optical coupling layers and processes for using them to laminate light extraction films to OLED devices are described, for example, in U.S. patent application Ser. No. 13/050,324, entitled “OLED Light Extraction Films Having Nanoparticles and Periodic Structures,” and filed Mar. 17, 2011.

The nanostructures 115 for light extraction film 110 can be particulate nanostructures, non-particulate nanostructures, or a combination thereof. In some cases, the non-particulate nanostructures can comprise an engineered nanostructure having an engineered nanoscale pattern. The nanostructures 115 can be formed integrally with the substrate or in a layer applied to the substrate. For example, the nanostructures can be formed on the substrate by applying to the substrate a low-index material and subsequently patterning the material. In some cases, the nanostructures can be embossed into a surface of the substantially transparent substrate 112. Engineered nanostructures are structures having at least one dimension, such as width, less than 1 micron. Engineered nanostructures are not individual particles but may be composed of nanoparticles forming the engineered nanostructures where the nanoparticles are significantly smaller than the overall size of the engineered structures.

The engineered nanostructures for light extraction film 110 can be one-dimensional (1D), meaning they are periodic in only one dimension, that is, nearest-neighbor features are spaced equally in one direction along the surface, but not along the orthogonal direction. In the case of 1D periodic nanostructures, the spacing between adjacent periodic features is less than 1 micron. One-dimensional structures include, for example, continuous or elongated prisms or ridges, or linear gratings. In some cases, the nanostructured layer 114 can comprise nanostructures 115 having a variable pitch. In one particular embodiment, the nanostructured layer 114 can comprise nanostructures having a pitch of about 400 nm, about 500 nm, about 600 nm, or a combination thereof.

The engineered nanostructures for light extraction film 110 can also be two-dimensional (2D), meaning they are periodic in two dimensions, that is, nearest neighbor features are spaced equally in two different directions along the surface. Examples of engineered nanostructures can be found, for example, in U.S. patent application Ser. No. 13/218,610 (Attorney Docket No. 67921US002), filed on Aug. 26, 2011. In the case of 2D nanostructures, the spacing in both directions is less than 1 micron. Note that the spacing in the two different directions may be different. Two-dimensional structures include, for example, lenslets, pyramids, trapezoids, round or square shaped posts, or photonic crystal structures. Other examples of two-dimensional structures include curved sided cone structures as described in U.S. Pat. Application Publication No. 2010/0128351.

Materials for the substrates, nanostructures, and backfill layers for light extraction film 110 are provided in the published patent applications identified above. For example, the substrate can be implemented with glass, PET, polyimides, TAC, PC, polyurethane, PVC, or flexible glass. Processes for making light extraction film 110 are also provided in the published patent applications identified above. Optionally, the substrate can be implemented with a barrier film to protect a device incorporating the light extraction film from moisture or oxygen. Examples of barrier films are disclosed in U.S. Pat. Application Publication No. 2007/0020451 and U.S. Pat. No. 7,468,211.

### EXAMPLES

All parts, percentages, ratios, etc. in the examples are by weight, unless noted otherwise. Solvents and other reagents used were obtained from Sigma-Aldrich Chemical Company; Milwaukee, Wis. unless specified differently.

### Materials

| Abbreviation/ | | |
|---|---|---|
| product name | Description | Available from |
| 3-mercaptopropyl | Chain Transfer | Alfa Aesar, Ward |
| trimethoxysilane | Agent, 95% | Hill, MA |
| IRGACURE 184 | Photoinitiator | Ciba Specialty Chem- |
| | | icals, Tarrytown, NY |
| MoO₃ | PURATRONIC MoO_{3,} | Alfa Aesar, |
| | 99.9995% metals basis | Ward Hill, MA |
| Nagase | UV curable epoxy resin | Nagase chemteX |
| XNR5516Z-B1 | | Corp., Japan |
| PHOTOMER 6210 | aliphatic urethane | Cognis Corporation, |
| | diacrylate | Cincinnati, OH |
| SOLPLUS D510 | polyester-polyamine | Lubrizol, |
| | copolymer | Cleveland, OH |
| SR238 | 1,6 hexanediol diacrylate | Sartomer Company, |
| | | Exton, PA |
| SR833S | difunctional acrylate | Sartomer Company, |
| | monomer | Exton, PA |
| ZnSe | ZnSe, 99.999% metals | Alfa Aesar, |
| | basis, powder | Ward Hill, MA |

### Preparative Examples

### Preparation of D510 Stabilized 50 nm TiO₂ Nanoparticle Dispersions

A TiO₂ nanoparticle dispersion with an approximately 52% wt of TiO₂ was prepared using a milling process in the presence of SOLPLUS D510 and 1-methoxy-2-propanol. The SOLPLUS D510 was added in an amount of 25% wt based on TiO₂ weight. The mixture was premixed using a DISPERMAT mixer (Paul N. Gardner Company, Inc., Pompano Beach, Fla.) for 10 minutes and then a NETZSCH MiniCer Mill (NETZSCH Premier Technologies, LLC., Exton, Pa.) was used with the following conditions: 4300 rpm, 0.2 mm YTZ milling media, and 250 ml/min flow rate. After 1 hour of milling, a white paste-like TiO₂ dispersion in 1-methoxy-2-propanol was obtained. The particle size was determined to be 50 nm (Z-average size) using a Malvern Instruments ZETASIZER Nano ZS (Malvern Instruments Inc, Westborough, Mass.).

### Preparation of High Index Backfill Solution (HI-BF).

20 g of D510 stabilized 50 nm TiO₂ solution, 2.6 g of SR833S, 0.06 g of IRGACURE 184, 25.6 g of 1-methoxy-2-propanol, 38.4 g of 2-butanone were mixed together to form a homogenous high index backfill solution.

Fabrication of Nanostructured Extractor Film with 400 nm Pitch.

A 400 nm “sawtooth” grating film was fabricated by first making a multi-tipped diamond tool as described in U.S. Pat. No. 7,140,812 (using a synthetic single crystal diamond, Sumitomo Diamond, Japan).

The diamond tool was then used to make a copper micro-replication roll which was then used to make 400 nm 1D structures on a PET film in a continuous cast and cure process utilizing a polymerizable resin made by mixing 0.5% (2,4,6 trimethyl benzoyl) diphenyl phosphine oxide into a 75:25 blend of PHOTOMER 6210 and SR238.

HI-BF solution was coated onto the 400 nm pitch 1D structured film using a roll to roll coating process with a web speed of 4.5 m/min (15 ft/min) and a dispersion delivery rate of 5.1 cc/min. The coating was dried in air at room temperature, then subsequently further dried at 82° C. (180° F.) and then cured using a Fusion UV-Systems Inc. Light-Hammer 6 UV (Gaithersburg, Md.) processor equipped with an H-bulb, operating under nitrogen atmosphere at 75% lamp power at a line speed of 4.5 m/min (15 ft/min).

### Examples 1 and 2, and Comparative Example C1

### Device Fabrication

Top Emissive (TE) OLED test coupons were built using standard thermal deposition in a vacuum system at base pressure of about 10⁻⁶ Torr. An Ag substrate with 10 nm ITO was fabricated on polished float glass with a 0.5 μm thick photoresist coating and 100 nm Ag/10 nm ITO coatings patterned to produce four 5×5 mm pixels in a square arrangement. A pixel defining layer (PDL) was applied to reduce the square size to 4×4 mm and provide clearly defined pixel edges. The following layered structure was built:
Ag substrate with 10 nm ITO and PDL/155 nm HIL/10 nm HTL/40 nm Green EML/35 nm ETL/Cathode/CPL
   where HIL, HTL, EML and ETL were, respectively, the hole-injection, hole-transport, emissive and electron-transport layers. The cathode was a 1 nm LiF/2 nm Al/20 nm Ag stack patterned via shadow masks to align with the substrate layer. For Example 1, 60 nm thick ZnSe was used as the capping layer, while for Example 2 400 nm thick ZnSe was used as the capping layer. The capping layer (CPL) for Comparative Example C1 was 400 nm thick MoO₃. Typical values of refractive index cited in published literature for MoO₃ range from 1.7-1.9. The MoO₃ in Comparative Example C1 was deposited on a substrate kept at room temperature, which results in a refractive index of approximately 1.71 measured at a wavelength at 600 nm, as reported in “Optical characterization of MoO₃ thin films produced by continuous wave CO₂ laser-assisted evaporation”, Cárdenas et al., Thin Solid Films, Vol. 478, Issues 1-2, Pages 146-151, May 2005. Typical values of refractive index cited in published literature for ZnSe range from 2.4-2.6.

Following device fabrication and prior to encapsulation, a 400 nm pitch 1D-symmetric extractor backfilled with a high refractive index as described under “Fabrication of nanostructured film with 400 nm pitch” was applied onto two pixels out of four on each test coupon using an optical coupling layer prepared as described in Example 7 of U.S. Provisional application No. 61/604,169 except that in the synthesis of Polymer-II, 2.0 g of 3-mercaptopropyl trimethoxysilane was used instead of 3.7 g. The optical coupling layer had a refractive index of about 1.7. The extractor lamination was conducted under inert (N₂) atmosphere and was followed by protecting under a glass lid attached by applying Nagase XNR5516Z-B1 UV-curable epoxy around the perimeter of the lid and cured with a UV-A light source at 16 Joules/cm² for 400 seconds.

Electrical and optical performance of the fabricated devices were evaluated using a set of standard OLED measurement techniques, including luminance-current-voltage measurements using a PR650 camera (Photo Research, Inc., Chatsworth, Calif.) and Keithley 2400 Sourcemeter (Keithley Instrumemts, Inc., Cleveland, Ohio), angular luminance and electroluminescence spectra measurements using an AUTRONIC Conoscope (AUTRONIC-MELCHERS GmbH, Karlsruhe, Germany), and goniometric measurements using the PR650 camera. The pixels without nanostructures were tested as controls.

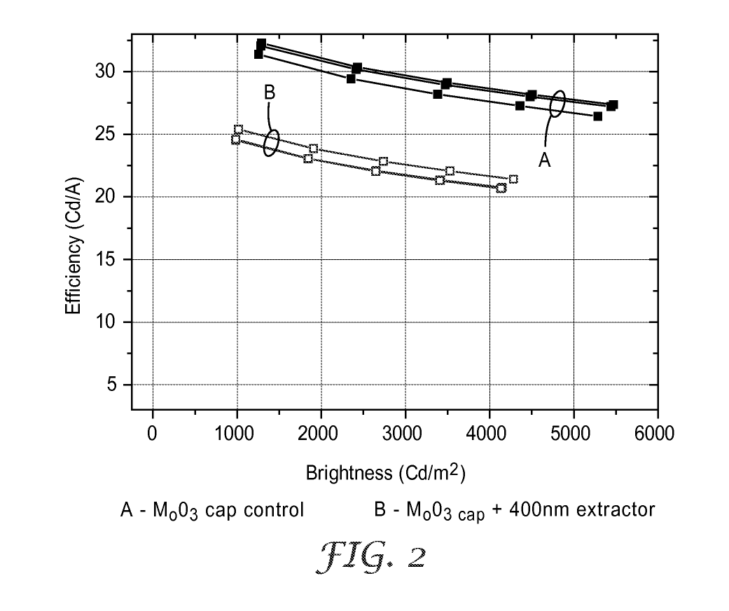

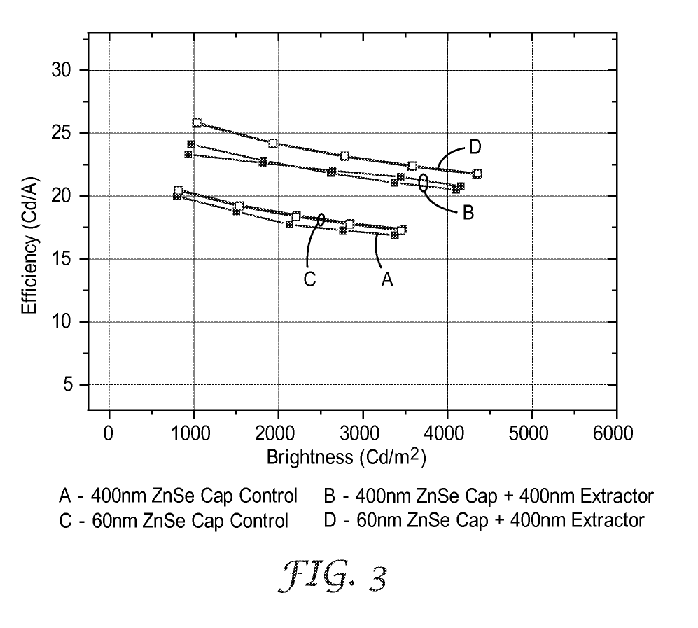

FIGS. 2 and 3 show efficiency vs luminance for control and extractor-laminated devices with the two types of capping layers. In FIG. 2, the performance of Comparative Example C1 control without extraction is labeled “A”, and with extraction is labeled “B”. Comparative Example C1 including the laminated nanostructured extractor with the MoO₃ capping layer, resulted in lower efficiency than without the extractor.

In FIG. 3, the performance of Example 1, the device with the 400 nm ZnSe capping layer is labeled “A” without the extractor (control), and labeled “B” with the extractor. Also shown in FIG. 3, the performance of Example 2, the device with the 60 nm ZnSe capping layer is labeled “C” without the extractor (control), and labeled “D” with the extractor. The ZnSe capping layer, which had a refractive index of at least 2.4, produced about 1.2-1.3× on-axis gains with the laminated nanostructure extractor compared to the control samples not having an extractor. Conoscopic images confirmed that the ZnSe capped device showed axial and integrated gains with the nanostructured extractor, while losses were observed with the MoO₃ device having the nanostructured extractor.

### Example 3

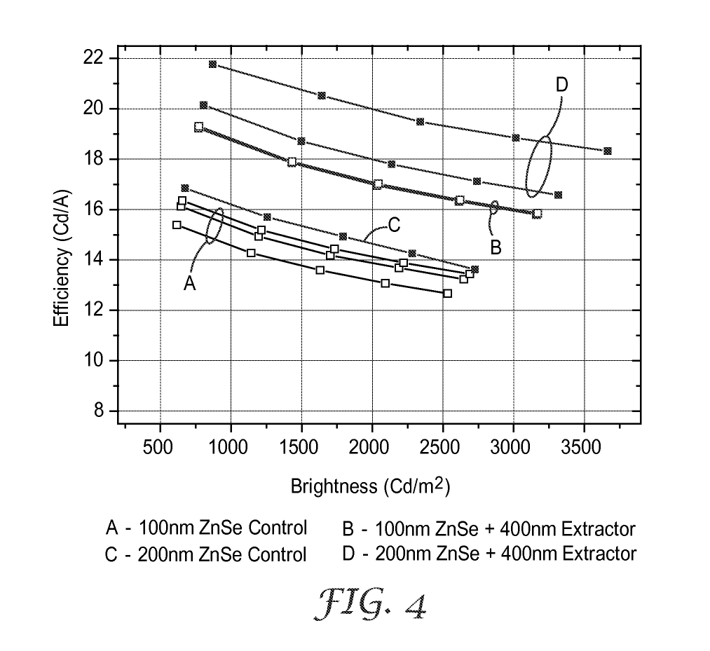

Devices with variable capping layer (CPL) thicknesses were built according to the procedure described above in Device Fabrication. CPL thickness values produced were 60, 100, 200 and 400 nm. FIG. 4 shows efficiency vs luminance for control and extractor-laminated devices with 100 and 200 nm thick ZnSe CPL. In FIG. 4, the 100 nm ZnSe CPL control without extractor is labeled “A”; the 100 nm ZnSe CPL with 400 nm extractor is labeled “B”; the 200 nm ZnSe CPL control without extractor is labeled “C”; and the 200 nm ZnSe CPL with 400 nm extractor is labeled “D”.

Axial efficiency of the control devices depended to some extent on the thickness of ZnSe capping layer, but for each thickness tested, laminated extractors produced gains generally in the range of about 1.2-1.3× as shown in FIG. 4. Similarly, conoscopic analysis of the devices with various ZnSe CPL thickness and nanostructured extractor revealed strong axial gains (1.2-1.3×), strong integrated gains (up to 1.4-1.6×) and wider luminance angular distribution compared with the control samples.

### Example 4

Devices with various cavity lengths were built according to the procedure described above in Device Fabrication. Cavity length was controlled by changing the thickness of the electron-transport layer (ETL). ETL thickness values produced were 25, 35, and 45 nm, which corresponded to cavity length values, respectively, of 215, 225, and 235 nm, respectively.

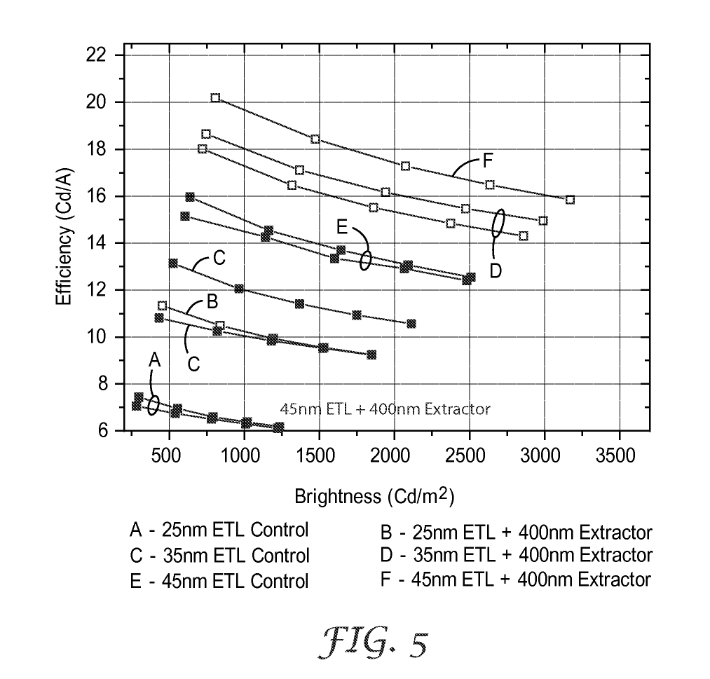

FIG. 5 shows efficiency vs luminance for control and extractor-laminated devices with 25, 35 and 45 nm thick ETL. In FIG. 5, the 25 nm ETL control without extractor is labeled “A”; the 25 nm ETL control with extractor is labeled “B”; the 35 nm ETL control without extractor is labeled “C”; the 35 nm ETL control with extractor is labeled “D”; the 45 nm ETL control without extractor is labeled “E”; and the 45 nm ETL control with extractor is labeled “F”. Even though control performance varied substantially for the various cavity length structures, strong optical gains were observed across the entire range of device thicknesses. This trend continued at other prepared cavity length/device thickness values. Conoscopic analysis confirmed that extraction gains and improved luminance uniformity were achieved with laminated devices across the entire range of cavity length values tested.

Following are a list of embodiments of the present disclosure.

Item 1 is a light emitting device, comprising: a microcavity organic light emitting diode (OLED) device having a top metal electrode configured to emit light; a capping layer having an index of refraction greater than 1.8 disposed immediately adjacent the top metal electrode; and a light extraction film disposed adjacent the capping layer.

Item 2 is the light emitting device of item 1, wherein the capping layer has an index of refraction greater than 1.9.

Item 3 is the light emitting device of item 1 or item 2, wherein the capping layer has an index of refraction greater than 2.0.

Item 4 is the light emitting device of item 1 to item 3, wherein the light extraction film comprises a layer of nanostructures and a backfill layer disposed over the nanostructures and adjacent the capping layer, the backfill layer having an index of refraction greater than the index of refraction of the nanostructures.

Item 5 is the light emitting device of item 4, wherein the backfill layer comprises an adhesive for bonding the light extraction film to the capping layer.

Item 6 is the light emitting device of item 1 to item 5, further comprising an adhesive optical coupling layer disposed immediately adjacent the capping layer.

Item 7 is the light emitting device of item 4 to item 6, wherein the light extraction film further comprises a substrate substantially transparent to light emitted by the microcavity OLED device, disposed adjacent the layer of nanostructures.

Item 8 is the light emitting device of item 4 to item 7, wherein the layer of nanostructures are embossed into a surface of a substrate substantially transparent to light emitted by the microcavity OLED device.

Item 9 is the light emitting device of item 4 to item 8, wherein the layer of nanostructures comprise particulate nanostructures, non-particulate nanostructures, or a combination thereof.

Item 10 is the light emitting device of item 9, wherein the non-particulate nanostructures comprise an engineered nanoscale pattern.

Item 11 is the light emitting device of item 4 to item 10, wherein the backfill layer comprises a non-scattering nanoparticle filled polymer.

Item 12 is the light emitting device of item 1 to item 11, wherein the top electrode is a partially transparent electrode comprising a metal having a thickness less than about 30 nm.

Item 13 is the light emitting device of item 1 to item 12, wherein the capping layer comprises zinc selenide, silicon nitride, indium tin oxide, or a combination thereof.

Item 14 is the light emitting device of item 1 to item 13, wherein the capping layer comprises a thickness between about 60 nm and 400 nm.

Item 15 is the light emitting device of item 1 to item 14, wherein the light extraction film comprises nanostructures having a variable pitch.

Item 16 is the light emitting device of item 1 to item 15, wherein the light extraction film comprises nanostructures having a pitch of about 400 nm, about 500 nm, about 600 nm, or a combination thereof.

Item 17 is an active matrix organic light emitting diode (AMOLED) device, comprising: an array of light emitting devices, each light emitting device comprising: a microcavity organic light emitting diode (OLED) device having a top metal electrode configured to emit light; a capping layer having an index of refraction greater than 1.8 disposed immediately adjacent the top metal electrode; and a light extraction film disposed over the array of light emitting devices, the light extraction film adjacent the capping layer.

Item 18 is the light emitting device of item 17, wherein the capping layer has an index of refraction greater than 1.9.

Item 19 is the light emitting device of item 17 or item 18, wherein the capping layer has an index of refraction greater than 2.0.

Item 20 is the AMOLED device of item 17 to item 19, wherein the light extraction film comprises a substrate substantially transparent to light emitted by the microcavity OLED device, a layer of nanostructures applied to the substrate, and a backfill layer disposed over the nanostructures and adjacent the capping layer, the backfill layer having an index of refraction greater than the index of refraction of the nanostructures.

Item 21 is the AMOLED device of item 20, wherein the backfill layer comprises an adhesive for bonding the light extraction film to the capping layer.

Item 22 is the AMOLED device of item 17 to item 21, further comprising an adhesive optical coupling layer disposed immediately adjacent the capping layer.

Item 23 is the AMOLED device of item 17 to item 22, wherein the capping layer comprises zinc selenide, silicon nitride, indium tin oxide, or a combination thereof.

Item 24 is an image display device, comprising: a plurality of light emitting devices, each light emitting device comprising: a microcavity organic light emitting diode (OLED) device having a top metal electrode configured to emit light; a capping layer having an index of refraction greater than 1.8 disposed immediately adjacent the top metal electrode; a light extraction film disposed over the plurality of light emitting devices, the light extraction film adjacent the capping layer; and an electronic circuit capable of activating each of the light emitting devices.

Item 25 is the light emitting device of item 24, wherein the capping layer has an index of refraction greater than 1.9.

Item 26 is the light emitting device of item 24 or item 25, wherein the capping layer has an index of refraction greater than 2.0.

Item 27 is the image display device of item 24 to item 26, wherein the plurality of light emitting devices comprise an active matrix organic light emitting diode (AMOLED) device

Unless otherwise indicated, all numbers expressing feature sizes, amounts, and physical properties used in the specification and claims are to be understood as being modified by the term “about”. Accordingly, unless indicated to the contrary, the numerical parameters set forth in the foregoing specification and attached claims are approximations that can vary depending upon the desired properties sought to be obtained by those skilled in the art utilizing the teachings disclosed herein.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A light emitting device, comprising:
a microcavity organic light emitting diode (OLED) device having a top metal electrode configured to emit light;
a capping layer having an index of refraction greater than 1.8 disposed immediately adjacent the top metal electrode; and
a light extraction film disposed adjacent the capping layer.

2. The light emitting device of claim 1, wherein the capping layer has an index of refraction greater than 1.9.

3. (canceled)

4. The light emitting device of claim 1, wherein the light extraction film comprises a layer of nanostructures and a backfill layer disposed over the nanostructures and adjacent the capping layer, the backfill layer having an index of refraction greater than the index of refraction of the nanostructures.

5. (canceled)

6. The light emitting device of claim 1, further comprising an adhesive optical coupling layer disposed immediately adjacent the capping layer.

7. The light emitting device of claim 4, wherein the light extraction film further comprises a substrate substantially transparent to light emitted by the microcavity OLED device, disposed adjacent the layer of nanostructures.

8. The light emitting device of claim 4, wherein the layer of nanostructures are embossed into a surface of a substrate substantially transparent to light emitted by the microcavity OLED device.

9. The light emitting device of claim 4, wherein the layer of nanostructures comprise particulate nanostructures, non-particulate nanostructures, or a combination thereof.

10. The light emitting device of claim 9, wherein the non-particulate nanostructures comprise an engineered nanoscale pattern.

11. (canceled)

12. The light emitting device of claim 1, wherein the top electrode is a partially transparent electrode comprising a metal having a thickness less than about 30 nm.

13. The light emitting device of claim 1, wherein the capping layer comprises zinc selenide, silicon nitride, indium tin oxide, or a combination thereof.

14. The light emitting device of claim 1, wherein the capping layer comprises a thickness between about 60 nm and 400 nm.

15. The light emitting device of claim 1, wherein the light extraction film comprises nanostructures having a variable pitch.

16. (canceled)

17. An active matrix organic light emitting diode (AMOLED) device, comprising:
an array of light emitting devices, each light emitting device comprising:
a microcavity organic light emitting diode (OLED) device having a top metal electrode configured to emit light;
a capping layer having an index of refraction greater than 1.8 disposed immediately adjacent the top metal electrode; and
a light extraction film disposed over the array of light emitting devices, the light extraction film adjacent the capping layer.

18. The light emitting device of claim 17, wherein the capping layer has an index of refraction greater than 1.9.

19. (canceled)

20. The AMOLED device of claim 17, wherein the light extraction film comprises a substrate substantially transparent to light emitted by the microcavity OLED device, a layer of nanostructures applied to the substrate, and a backfill layer disposed over the nanostructures and adjacent the capping layer, the backfill layer having an index of refraction greater than the index of refraction of the nanostructures.

21. The AMOLED device of claim 20, wherein the backfill layer comprises an adhesive for bonding the light extraction film to the capping layer.

22. (canceled)

23. The AMOLED device of claim 17, wherein the capping layer comprises zinc selenide, silicon nitride, indium tin oxide, or a combination thereof.

24. An image display device, comprising:
a plurality of light emitting devices, each light emitting device comprising:
a microcavity organic light emitting diode (OLED) device having a top metal electrode configured to emit light;
a capping layer having an index of refraction greater than 1.8 disposed immediately adjacent the top metal electrode;
a light extraction film disposed over the plurality of light emitting devices, the light extraction film adjacent the capping layer; and
an electronic circuit capable of activating each of the light emitting devices.

25. The light emitting device of claim 24, wherein the capping layer has an index of refraction greater than 1.9.

26. (canceled)

27. The image display device of claim 24, wherein the plurality of light emitting devices comprise an active matrix organic light emitting diode (AMOLED) device.
